(19) United States
(12) Patent Application Publication
(10) Pub. No.: US 2014/0127424 A1
(43) Pub. Date: May 8, 2014

(54) Method and Apparatus for Bonding Functional Groups to the Surface of a Substrate

(71) Applicant: FORD GLOBAL TECHNOLOGIES, LLC, Dearborn, MI (US)

(72) Inventors: Daniel Quinn Houston, Dearborn, MI (US); Patrick James Blanchard, Ann Arbor, MI (US); Haibo Zhao, Northville, MI (US)

(73) Assignee: FORD GLOBAL TECHNOLOGIES, LLC, Dearborn, MI (US)

(21) Appl. No.: 13/671,833

(22) Filed: Nov. 8, 2012

(51) Int. Cl. C23C 16/513

(52) U.S. Cl. CPC C23C 16/513
USPC 427/569; 118/723 R

(57) ABSTRACT

A surface treatment method, machine, and system are disclosed for treating the surface of a substrate by providing a plasma jet generator that directs plasma through a gaseous composition to decompose the gaseous composition into functional groups. A carbon fiber substrate is disclosed that is treated by a plasma jet generator that is directed toward the surface through steam. The plasma jet generator bombards a carbon fiber surface with high energy ions. Carbon-to-carbon chains in the carbon fiber partially break and hydroxide ions are bonded to fractures in the carbon-to-carbon chains. The treatment bonds new hydroxide functional groups to the carbon fiber surface.

### TECHNICAL FIELD

This disclosure relates to a process for modifying the surface of a substrate to include additional functional groups.

### BACKGROUND

Surface treatments for carbon fibers, polymeric composites, glass fibers, metallic substrates, ceramic substrates and glass substrates includes flame treatment, corona treatment, and air plasma treatment. Such surface treatments are known to be used to add a limited number of functional groups to a surface. Functional groups may be added to promote adhesion and increase surface wetting.

One example of a functional group is a hydroxyl functional group (OH−). Other types of functional groups may also be grafted onto a substrate. Using flame treatment, corona treatment, or air plasma treatment only adds a limited number of functional groups to a surface due to the limited availability of sources of hydroxyl ions and other ions in the atmosphere.

There is a need for a cost-effective and robust process for enhancing interfacial adhesion between polymeric resins and carbon, metal, ceramic and glass substrates. One example of such a substrate is a carbon fiber reinforced polymeric composite that may offer one potential solution to the problem of reducing the weight of vehicle components to achieve better fuel economy as required by government regulations.

In a carbon fiber reinforced polymeric composite, the majority of the loads are taken by the carbon fibers. The polymer transfers loads between the fibers. The load transfer efficiency of the polymer determines the mechanical performance of the composite part. The fiber/matrix interface in a conventional carbon fiber reinforced polymeric composite is limited to physical friction due to the lack of substantial chemical bonding to the surface.

Improving adhesion of the polymer to the carbon fiber surface may increase load transfer efficiency. Improved load transfer efficiency may result in a reduction in the required thickness of a carbon fiber composite part and a reduction in cost because less carbon fiber is required to handle a given load.

The above problems and other problems are addressed by this disclosure as summarized below.

### SUMMARY

The disclosed method and apparatus for adding functional groups to a surface of the substrate is unique and innovative because it increases the quantity of ions available in the plasma. For example, introducing steam into the plasma increases the availability of hydroxide (OH−) ions in the plasma. As a result, the number of hydroxyl groups on the surface may be increased.

According to one aspect of this disclosure, a method is provided for treating a substrate. This method includes the steps of providing a substrate to a tool and supplying a gaseous composition to the tool. A plasma jet generates plasma that decomposes the gaseous composition to form ions. Ions are incorporated into the plasma when the gaseous composition is ionized and the ions are more freely available to be bonded to the substrate.

According to other aspects of the method, the step of directing the plasma jet may further comprise fracturing the surface of the substrate. The substrate in one embodiment may be a carbon fiber and the gaseous composition may be steam that is decomposed to form hydroxyl ions and hydrogen ions. Carbon-to-carbon chains may be fractured to bond to new functional groups. The plasma jet may bond the hydroxyl ions to the carbon fiber substrate.

According to one aspect of this disclosure, a method is provided for making a carbon fiber reinforced polymeric composite. The method includes the steps of providing a carbon fiber substrate to a tool and supplying steam to the pre-treatment tool. A plasma jet is directed through the steam toward the carbon fiber substrate to decompose the steam to form hydroxyl ions and hydrogen ions. Some of the hydroxyl ions are then bonded to the carbon fiber.

According to other aspects of the method, the step of directing the plasma jet may further comprise fracturing a surface of the carbon fiber substrate. The method may further include covalently bonding the hydroxyl ions and hydrogen ions to the fractures in the carbon fiber substrate. The step of supplying steam may further comprise supplying water to a heating unit to form the steam, pressurizing the steam, and spraying the steam through a nozzle.

According to another aspect of this disclosure, a system is disclosed for making a carbon fiber reinforced polymeric composite from a carbon fiber substrate and a polymer resin. The system comprises a steam generator that provides steam to a pre-treatment chamber that contains the carbon fiber substrate, and a plasma jet that directs plasma towards the carbon fiber substrate through the steam. The plasma jet may be used to decompose the steam to form hydroxyl ions and hydrogen ions and bond the hydroxyl ions to the carbon fiber.

Other aspects of the disclosed system are directed to the concept of using the plasma jet to fracture a surface of the carbon fiber substrate to facilitate bonding the hydroxyl ions to the carbon fiber. The steam generator may further include a water feed system that supplies water and a heating unit that heats the water to form steam. A pump may be operatively connected to the heating unit to apply pressure to the steam in the heating unit. A spray nozzle may be used to spray the steam between the plasma jet and the carbon fiber substrate. The steam generator may further include a mass flow controller that controls the quantity of water provided by the water feed system to the heating unit.

The above aspects of the disclosure and other aspects will be described in detail below with reference to the attached drawings.

### BRIEF DESCRIPTION OF THE DRAWINGS

FIG. 1 is a diagrammatic representation of a machine for bonding functional groups to the surface of a substrate; and

FIG. 2 is a diagrammatic representation of a carbon substrate after being subjected to the pre-treatment process performed by the machine such as that illustrated in FIG. 1.

### DETAILED DESCRIPTION

A detailed description of the illustrated embodiments of the present invention is provided below. The disclosed embodiments are examples of the invention that may be embodied in various and alternative forms. The figures are not necessarily to scale. Some features may be exaggerated or minimized to show details of particular components. The specific structural and functional details disclosed in this application are not to be interpreted as limiting, but merely as a representative basis for teaching one skilled in the art how to practice the invention.

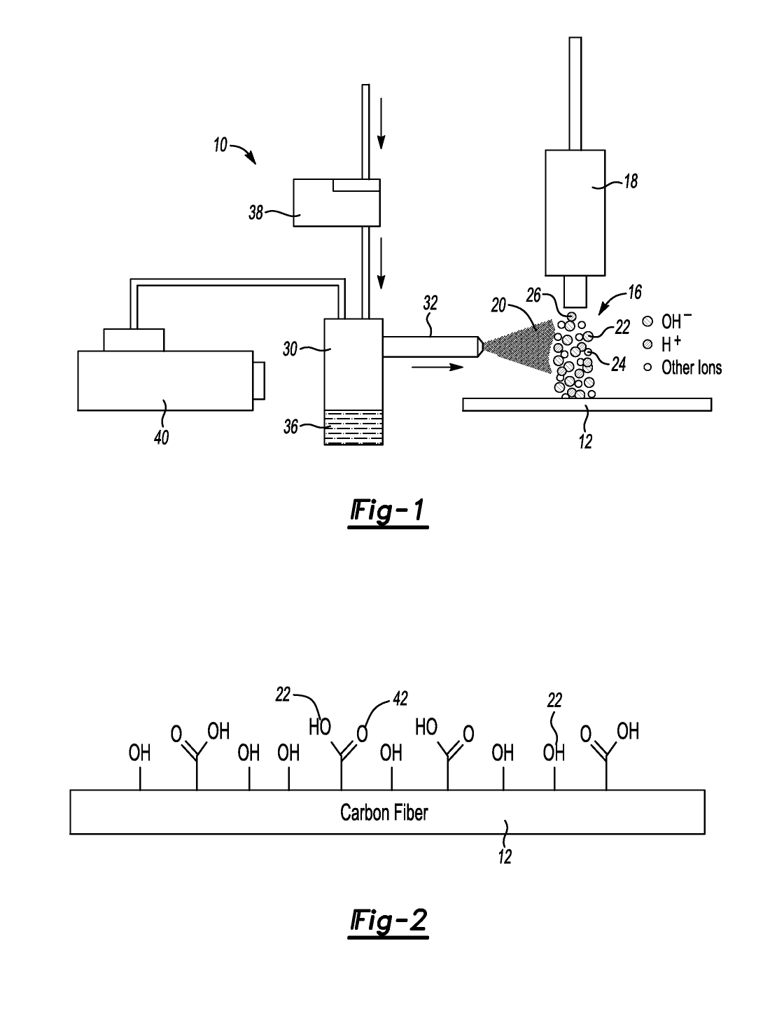

Referring to FIG. 1, a surface treatment machine 10 is shown in the process of pre-treating a substrate material, such as carbon fiber 12. Other substrate materials that may be used include polymeric composites, glass fibers, metal substrates, ceramic substrates and glass substrates. Plasma, generally indicated by reference numeral 16, is created by a plasma jet 18. The plasma jet 18 creates excited gas atoms and molecules with high gas temperatures.

A gaseous composition, such as steam 20 is provided between the plasma jet 18 and the substrate. As described herein the gaseous composition provided or supplied to the plasma 16 is distinguished from using a plasma jet 18 through the atmosphere because normally occurring gases in the atmosphere fail to provide sufficient functional groups for treating the surface of a substrate. Other precursors for (OH−) functional groups include methanol, alcohol, and the like. Other gaseous compositions that may be introduced into the plasma 16 include precursors for aminogen (NH2−) functional groups that include ammonia(NH₃), hydroxylamine(NH₃OH), or the like. In one example, the substrate may be carbon fiber 12 and the gaseous composition may be steam 20 that facilitates forming plasma 16 that includes OH− ions 22, H+ ions, and other ions 24 that are created by the plasma 16. The steam 20 is decomposed into the hydroxyl ions 22 and the hydrogen ions 24 by the plasma jet.

The steam 20 is created by a heating unit 30 that supplies the steam 20 through a nozzle 32. The nozzle 32 directs the steam 20 into the plasma 16 created by the plasma jet 18. The plasma 16 breaks down the water molecules and the steam 20 into the OH− 22 ions and the H+ions 24. Water 36 is heated in the heating unit 30 to create the steam 20. A mass flow controller 38 is used to control the rate at which water 36 is provided to the heating unit 30. A pump 40 pumps air into the heating unit 30 to provide additional pressure at a controlled level to the heating unit 30.

Referring to FIG. 2, a carbon fiber 12 is illustrated after being pre-treated in the surface treatment machine 10 shown in FIG. 1. The carbon fiber 12 surface is bombarded with high energy ions created by the plasma 16. Carbon-to-carbon chains in the carbon fiber may partially fracture and may be reunited with OH− ions 22. The OH− ions 22 establish new functional groups on the carbon fiber surface and form a covalent bond with the carbon-to-carbon chains.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A method of treating a substrate, comprising:
providing a substrate;
supplying a gaseous composition;
directing a plasma jet through the gaseous composition toward the substrate to decompose the gaseous composition to form ions; and
bonding the ions to the substrate.

2. The method of claim 1 wherein during the step of directing the plasma jet generator further comprises fracturing a surface of the substrate.

3. The method of claim 1 wherein the substrate is carbon fiber, the gaseous composition is steam that is decomposed to form hydroxide ions and hydrogen ions, and wherein the step of directing the plasma jet further comprises covalently bonding the hydroxide ions to the carbon fiber substrate.

4. The method of claim 1 wherein the step of supplying the gaseous composition further comprises:
supplying water to a heating unit to form the a volume of steam;
pressurizing the steam; and
spraying the steam through a nozzle.

5. The method of claim 4 wherein the substrate is carbon fiber that is used to make a reinforced polymeric composite, wherein the gaseous composition is steam, and the step of directing the plasma jet decomposes the steam into hydroxide ions and hydrogen ions, and wherein during the bonding step hydroxide ions are bonded to the carbon fiber substrate.

6. The method of claim 1 wherein the substrate is selected from the group consisting essentially of:
carbon fibers;
glass fibers;
polymeric composites;
metal surfaces;
ceramic surfaces; and
glass surfaces.

7. The method of claim 1 wherein the gaseous composition is selected from the group consisting essentially of:
steam;
methanol;
alcohol;
ammonia; and
hydroxylamine.

8. A system for making a carbon fiber reinforced polymeric composite, comprising:
a carbon fiber substrate;
a tool that receives the carbon fiber substrate;
a steam generator that supplies steam to the tool; and
a plasma jet generator that directs plasma through the steam toward the carbon fiber substrate to decompose the steam and form hydroxide ions and hydrogen ions, and bond the hydroxide ions to the carbon fiber substrate.

9. The system of claim 8 wherein the plasma jet generator fractures a surface of the carbon fiber substrate.

10. The system of claim 8 wherein the hydroxide ions are covalently bonded to the carbon fiber.

11. The system of claim 8 wherein a quantity of water is provided to a heating unit to form the steam, a pump is provided to pressurize the steam, and a nozzle is provided to spray the steam.

12. The system of claim 11 wherein the quantity of water supplied to the heating unit is controlled by a mass flow controller.

13. A machine for treating a substrate comprising:
a steam generator that provides steam to a treatment chamber that contains the substrate; and
a plasma jet that directs plasma towards the substrate through the steam, wherein the plasma jet decomposes the steam to form hydroxide ions and hydrogen ions and bonds the hydroxide ions to the substrate.

14. The machine of claim 13 wherein the plasma jet fractures a surface of the carbon fiber substrate to facilitate bonding the hydroxide ions to the carbon fiber.

15. The machine of claim 13 wherein the steam generator further includes:
a water feed system that supplies water;
a heating unit that heats the water to form steam;
a pump operatively connected to the heating unit to apply pressure to the steam in the heating unit; and
a spray nozzle that sprays the steam between the plasma jet and the carbon fiber substrate.

16. The machine of claim 13 wherein the substrate is carbon fiber, and wherein the hydroxyl ions are bond to the carbon fiber to provide a plurality of functional groups for bonding to a polymeric resin.

17. The method of claim 13 wherein the substrate is selected from the group consisting essentially of:
carbon fibers;
glass fibers;
polymeric composites;
metal surfaces;
ceramic surfaces; and
glass surfaces.
